(19) United States
(12) Patent Application Publication
(10) Pub. No.: US 2022/0339749 A1
(43) Pub. Date: Oct. 27, 2022

(54) SUBSTRATE PROCESSING APPARATUS AND MANUFACTURING METHOD THEREOF

(71) Applicants: SEMES CO., LTD., Cheonan-si (KR); Shinil Chemical Industry Co., Ltd., Ansan-si (KR)

(72) Inventors: Sung Lin LEE, Pyeongtaek-si (KR); Sung Ho JANG, Cheonan-si (KR); Chul Woo KIM, Cheonan-si (KR); Dong Yol RYU, Ansan-si (KR); Bo Ram KWON, Namyangju-si (KR)

(73) Assignees: SEMES CO., LTD., Cheonan-si (KR); Shinil Chemical Industry Co., Ltd., Ansan-si (KR)

(21) Appl. No.: 17/699,108

(22) Filed: Mar. 19, 2022

(30) Foreign Application Priority Data
Apr. 27, 2021 (KR) 10-2021-0054554

(51) Int. Cl. B23Q 3/152; B05C 11/10; B05C 5/02; B29C 45/00

(52) U.S. Cl. CPC B23Q 3/152; B05C 11/1039; B05C 5/02; B29C 45/0001; B29C 45/0005; B23Q 2703/10; B29L 2031/7502

(57) ABSTRACT

A substrate processing apparatus includes a substrate support unit including a chuck for supporting a substrate, a fluid supply unit that supplies a processing fluid to the substrate, and a recovery unit surrounding the chuck and recovering the supplied processing fluid. The substrate support unit includes an antistatic material in which milled carbon fibers (MCF) are blended into a perfluoroalkoxy alkane (PFA) resin.

### CROSS REFERENCE TO RELATED APPLICATION

The present application claims priority to Korean Patent Application No. 10-2021-0054554, filed on Apr. 27, 2021, the entire contents of which is herein incorporated by this reference.

### BACKGROUND OF THE INVENTION

### 1. Field of the Invention

The present invention relates to a substrate processing apparatus and a manufacturing method thereof, and more particularly, to an apparatus that prevents static electricity generated during a process of processing a substrate and a method for manufacturing the apparatus.

### 2. Description of the Related Art

A semiconductor (or display) manufacturing process includes, for example, exposure, deposition, etching, ion implantation, and packaging as a process of manufacturing a semiconductor element on a substrate (for example, wafer). A manufacturing plant for manufacturing a semiconductor element includes clean rooms of one or more floors, and manufacturing facilities for performing a semiconductor manufacturing process are disposed on the floors.

In particular, a cleaning process of cleaning particles remaining on a substrate is performed before and after each process is performed. In the cleaning process, a processing fluid (for example, cleaning liquid) is supplied onto one or both sides of the substrate supported on a spin chuck. In one example, the processing fluid is supplied to the central region of the substrate, and the substrate is rotated by the spin chuck while the processing fluid is supplied to the substrate. The processing fluid supplied to the substrate may be scattered or diffused to the edge region of the substrate by the centrifugal force of the rotating substrate.

The processing fluid supplied to the substrate generates static electricity while rubbing against the surface of the substrate, and the generated static electricity may damage the substrate. For example, the static electricity generated when the processing fluid is supplied to the substrate has a problem that the static electricity moves charged particles around the substrate to the surface of the substrate by attraction, so as to contaminate the substrate or cause arcing, thereby damaging a pattern formed on the substrate. Thus, it is required to appropriately remove static electricity generated on the substrate.

### SUMMARY OF THE INVENTION

An object of the present invention is to provide a substrate processing apparatus capable of removing static electricity generated in a substrate or a process facility, by forming a component of a substrate periphery including an electrostatic chuck with an antistatic material.

In addition, an object of the present invention is to provide a substrate processing apparatus capable of efficiently removing static electricity generated in a substrate or process facility by grounding an antistatic material applied to a substrate processing apparatus. Another object of the present invention to provide a method of manufacturing a substrate processing apparatus by using an antistatic material which has a relatively low probability of acting as a particle source and is advantageous in terms of production efficiency, as compared to a conventional antistatic material.

The objects of the present invention are not limited to the above description, and other objects and advantages of the invention which are not mentioned can be clearly understood by those skilled in the art as described below.

According to an embodiment of the present invention, a substrate processing apparatus includes a substrate support unit that includes a chuck for supporting a substrate, a fluid supply unit that supplies a processing fluid to the substrate, and a recovery unit surrounding the chuck and recovering the supplied processing fluid. The substrate support unit may contain an antistatic material in which milled carbon fibers (MCF) are blended into a perfluoroalkoxy alkane (PFA) resin.

According to an embodiment of the present invention, a substrate processing facility includes a load port on which a carrier storing a substrate is mounted, a transport frame in which an index robot that conveys the substrate from the carrier mounted on the load port is provided, and a process processing module including a substrate processing apparatus that performs a liquid processing process on the substrate. The substrate processing apparatus may include a substrate support unit that includes a chuck for supporting a substrate, a fluid supply unit that supplies a processing fluid to the substrate, and a recovery unit that surrounds the chuck and recovers the supplied processing fluid. The substrate support unit includes an antistatic material in which milled carbon fibers (MCF) are blended into a perfluoroalkoxy alkane (PFA) resin.

According to an embodiment of the present invention, there is provided a manufacturing method of a substrate processing apparatus including a substrate support unit that includes a chuck for supporting a lower surface of a substrate and a chuck pin formed to come into contact with a side surface portion of the substrate, a fluid supply unit that supplies a processing fluid to the substrate, and a recovery unit that is disposed to surround the chuck and recovers the supplied processing fluid. In the above embodiment of the present invention, the manufacturing method of a substrate processing apparatus may include producing the chuck by injection processing by blending milled carbon fibers (MCF) into a perfluoroalkoxy alkane (PFA) resin, providing the chuck pin with a conductive material having resistance lower than the substrate, and grounding the chuck.

According to the present invention, it is possible to efficiently remove static electricity generated on the surface of a substrate or in a process chamber during a process.

Further, according to the present invention, it is possible to minimize particle contamination of a substrate, an occurrence of an arcing phenomena on the surface of the substrate, and damage to the pattern of the substrate.

The effects of the present invention are not limited to the effects described above, and effects not mentioned can be clearly understood by those skilled in the art, from the specification and the attached drawings.

### BRIEF DESCRIPTION OF THE DRAWINGS

The above and other objectives, features, and other advantages of the present disclosure will be more clearly understood from the following detailed description taken in conjunction with the accompanying drawings, in which:

FIG. 1 is a plan view schematically illustrating a substrate processing facility according to an embodiment of the present invention.

FIG. 2 is a cross-sectional view schematically illustrating a substrate processing apparatus in FIG. 1.

FIGS. 3A and 3B illustrate pyrolysis curves for comparing and explaining an antistatic material according to the embodiment of the present invention and an antistatic material in the related art.

FIG. 4 is an enlarged view for explaining a procedure of removing static electricity generated on a substrate by using the substrate processing apparatus according to the embodiment of the present invention.

FIG. 5 is a flow chart illustrating a procedure in which the substrate processing apparatus according to the embodiment of the present invention removes the static electricity generated on the substrate.

FIG. 6 is a cross-sectional view schematically illustrating a substrate processing apparatus according to an embodiment of the present invention.

FIG. 7 is an enlarged view for explaining a procedure of removing static electricity generated on a substrate by using a substrate processing apparatus according to the above embodiment of the present invention.

FIG. 8 is a flow chart illustrating a procedure in which the substrate processing apparatus according to the above embodiment of the present invention removes the static electricity generated on the substrate.

FIG. 9 is a flow chart schematically illustrating a manufacturing method of a substrate processing apparatus according to an embodiment of the present invention.

FIG. 10 is a flow chart schematically illustrating a manufacturing method of a substrate processing apparatus according to an embodiment of the present invention.

### DESCRIPTION OF EMBODIMENTS

Hereinafter, embodiments of the present invention will be described in detail with reference to the attached drawings to be easily implemented by those skilled in the art. The present invention may be implemented in various different forms and is not limited to the embodiments described herein.

In order to clearly describe the present invention, parts that are not related to the description will be omitted, and the same or similar components in this specification are denoted by the same reference sign.

In addition, in various embodiments, a component having the same configuration will be described only in a representative embodiment by using the same reference sign, and only a configuration that is different from that of the representative embodiment will be described in other embodiments.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. As used herein, components described as being “electrically connected” are configured such that an electrical signal can be transferred from one component to the other (although such electrical signal may be attenuated in strength as it transferred and may be selectively transferred). In addition, a sentence that a portion “includes” a component means that it may further include another component rather than excluding other components unless a particularly opposite statement is made.

Unless otherwise defined, all terms used herein, including technical or scientific terms, have the same meaning as generally understood by those skilled in the art. Terms such as those defined in a commonly used dictionary should be construed as having a meaning consistent with the meaning of the relevant technology, and should not be construed as an ideal or excessively formal meaning unless explicitly defined in this application.

Meanwhile, the size, the shape, and the line thickness of a component in a drawing may be somewhat exaggerated for convenience of understanding.

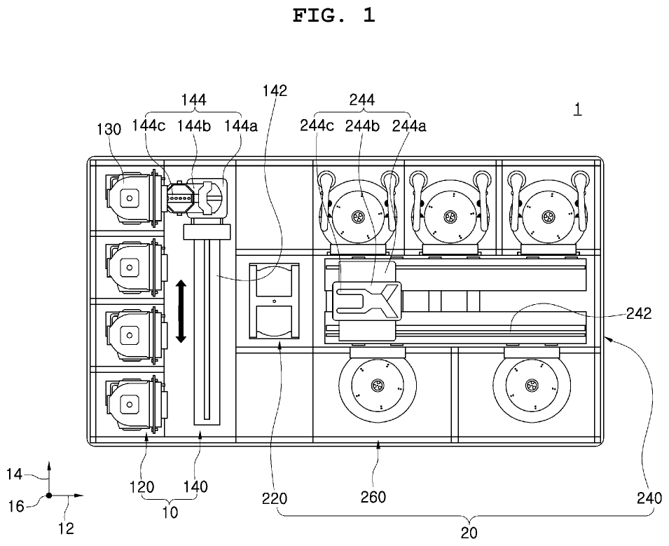

FIG. 1 illustrates the structure of a substrate processing facility to which a substrate processing apparatus according to an embodiment of the present invention is applied.

With reference to FIG. 1, a substrate processing facility 1 includes an index module 10 and a process processing module 20. The index module 10 includes a load port 120 and a transport frame 140. The load port 120, the transport frame 140, and the process processing module 20 are arranged sequentially in a row. A direction in which the load port 120, the transport frame 140, and the process processing module 20 are arranged is referred to as a first direction 12 below. When viewed from the top, a direction perpendicular to the first direction 12 is referred to as a second direction 14, and a direction perpendicular to a plane including the first direction 12 and the second direction 14 is referred to as a third direction 16.

A carrier 130 in which a substrate W is stored is mounted on the load port 120. A plurality of load ports 120 may be provided and may be arranged in a row along the second direction 14. FIG. 1 illustrates that four load ports 120 are provided. The number of load ports 120 may increase or decrease depending on conditions such as process efficiency and footprint of the process processing module 20. A slot (not illustrated) provided to support the edge of the substrate may be formed in the carrier 130. A plurality of slots may be provided in the third direction 16, and the substrate may be located in a carrier so as to be stacked at a distance from each other in the third direction 16.

A front opening unified pod (FOUP) may be used as the carrier 130.

The process processing module 20 may include a buffer unit 220, a transport chamber 240, and a process chamber 260. The transport chamber 240 may be disposed so that the longitudinal direction of the transport chamber is parallel to the first direction 12. The process chambers 260 may be arranged on both sides of the transport chamber 240 in the second direction 14. The process chambers 260 may be provided to be symmetrical with respect to the transport chamber 240. Some of the process chambers 260 may be arranged in the longitudinal direction of the transport chamber 240. Some of the process chambers 260 may be arranged to be stacked. That is, the process chambers 260 may be arranged on both sides of the transport chamber 240 in an arrangement of A×B (A and B are natural numbers of 1 or more). Here, A indicates the number of process chambers 260 provided in a row in the first direction 12, and B indicates the number of process chambers 260 provided in a row in the third direction 16. When four or six process chambers 260 are provided on each side of the transport chamber 240, the process chambers 260 may be arranged in an arrangement of 2×2 or 3×2. The number of process chambers 260 may increase or decrease.

In contrast to the above description, the process chamber 260 may be provided only on one side of the transport chamber 240. The process chamber 260 may also be provided in a single layer on one side and the other side of the transport chamber 240. The process chamber 260 may be provided in various arrangements in contrast to the above description. The process chambers located on one side of the transport chamber 240 among the process chambers 260 may perform a liquid processing process on the substrate, and the process chambers located on the other side may perform a process of drying the substrate subjected to the liquid processing process. The drying process may be a supercritical processing process.

The buffer unit 220 is disposed between the transport frame 140 and the transport chamber 240. The buffer unit 220 provides a space for the substrate W to stay before the substrate W is conveyed between the transport chamber 240 and the transport frame 140. The buffer unit 220 may be provided with a slot (not illustrated) in which a substrate W is placed, and a plurality of slots (not illustrated) may be provided at a distance from each other in the third direction 16. In the buffer unit 220, each of the surface facing the transport frame 140 and the surface facing the transport chamber 240 is opened.

The transport frame 140 conveys a substrate W between the carrier 130 mounted on the load port 120 and the buffer unit 220. The transport frame 140 is provided with an index rail 142 and an index robot 144. The index rail 142 is provided so that the longitudinal direction of the index rail is parallel to the second direction 14. The index robot 144 is installed on the index rail 142 and is moved along the index rail 142 in a straight line in the second direction 14. The index robot 144 includes a base 144a, a body 144b, and an index arm 144c. The base 144a is provided to be movable along the index rail 142. The body 144b is coupled to the base 144a. The body 144b is provided to be movable along the third direction 16 on the base 144a. The body 144b is provided to be rotatable on the base 144a. The index arm 144c may be coupled to the body 144b and be provided to be movable forward and backward with respect to the body 144b. A plurality of index arms 144c may be provided to be individually operated. The index arms 144c may be disposed to be stacked at a distance from each other in the third direction 16. Some of the index aims 144c are used to convey the substrate W from the process processing module 20 to the carrier 130, and others may be used to convey the substrate W from the carrier 130 to the process processing module 20. This makes it possible to prevent an occurrence of a situation in which particles generated from the substrate W before process processing adhere to the substrate W after the process processing in the middle of loading and exporting the substrate W by the index robot 144.

The transport chamber 240 conveys the substrate W between the buffer unit 220 and the process chambers 260. The transport chamber 240 is provided with a guide rail 242 and a main robot 244. The guide rail 242 is disposed so that the longitudinal direction of the guide rail is parallel to the first direction 12. The main robot 244 is installed on the guide rail 242 and is moved on the guide rail 242 along the first direction 12 in a straight line. The main robot 244 includes a base 244a, a body 244b, and a main aim 244c. The base 244a is provided to be movable along the guide rail 242. The body 244b is coupled to the base 244a. The body 244b is provided to be movable along the third direction 16 on the base 244a. The body 244b is provided to be rotatable on the base 244a. The main arm 244c is coupled to the body 244b and is provided to be movable forward and backward with respect to the body 244b. A plurality of main arms 244c are provided to be individually operated. The main aims 244c are disposed to be stacked at a distance from each other in the third direction 16.

A substrate processing apparatus that performs the liquid processing process, for example, a cleaning process, on the substrate W may be provided in the process chamber 260. For example, the cleaning process may be a process of cleaning the substrate W, stripping, and removing organic residue by using processing fluids containing an alcohol component. The substrate processing apparatus provided in each process chamber 260 may have a different structure depending on the type of cleaning process to be performed. Optionally, the substrate processing apparatus in each process chamber 260 may have the same structure. Optionally, the process chambers 260 are classified into a plurality of groups, so that the substrate processing apparatuses provided in the process chamber 260 belonging to the same group may have the same structure, and the substrate processing apparatuses provided in the process chamber 260 belonging to different groups may have different structures. An example of the substrate processing apparatus provided in the process chamber 260 will be described below.

A substrate processing apparatus 300 according to an embodiment of the present invention performs liquid processing on a substrate W by supplying a processing fluid onto the substrate W. In the present embodiment, description will be made on the assumption that the liquid processing process of a substrate is the cleaning process.

Such a liquid processing process is not limited to the cleaning process and can be applied in various processes such as photography, asking, and etching.

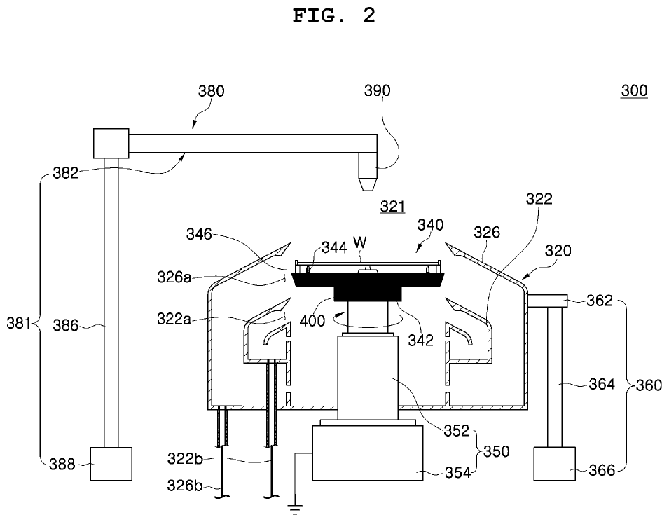

FIG. 2 is a cross-sectional view illustrating the substrate processing apparatus in FIG. 1. With reference to FIG. 2, the substrate processing apparatus 300 may include a recovery unit 320, a substrate support unit 340, a lifting unit 360, an upper fluid supply unit 380, a bottom fluid supply unit 400, and a controller (not illustrated).

The recovery unit 320 provides a processing space 321 in which a substrate is processed. The recovery unit 320 has a barrel shape with an open top portion. The recovery unit 320 includes an inner recovery cup 322 and an outer recovery cup 326. The recovery cups 322 and 326 recover processing fluids different from each other among the processing fluids used in the process. The inner recovery cup 322 is provided in an annular ring shape surrounding the substrate support unit 340. The outer recovery cup 326 is provided in an annular ring shape surrounding the inner recovery cup 322. An inner space 322a of the inner recovery cup 322 functions as a first inlet 322a through which the processing fluid flows into the inner recovery cup 322.

A space 326a between the inner recovery cup 322 and the outer recovery cup 326 functions as a second inlet 326a through which the processing fluid flows into the outer recovery cup 326. According to one example, the inlets 322a and 326a may be located at different heights. Recovery lines 322b and 326b are connected to the bottoms of the respective recovery cups 322 and 326. The processing fluids flowing into the recovery cups 322 and 326 can be provided through the recovery lines 322b and 326b to an external processing fluid regeneration system (not illustrated) for reuse, respectively.

The substrate support unit 340 supports a substrate W in the processing space. The substrate support unit 340 supports and rotates the substrate W during a process. The substrate support unit 340 includes a chuck 342, a support pin 344, a chuck pin 346, and a rotational drive member. The chuck 342 is generally provided in a disc shape and includes an upper surface and a bottom surface. The lower surface has a diameter smaller than the upper surface. The upper surface and the bottom surface are located so that center axes of the upper surface and the bottom surface coincide with each other.

Generally, a fluororesin (for example, perfluoroalkoxy alkane (PFA), polytetrafluoroethylene (PTEE), and the like) having favorable chemical resistance, thermal stability, and mass production properties is applied to the chuck, the recovery cup, and the nozzle of the substrate processing apparatus in order for the chuck, the recovery cup, and the nozzle to have stability against the processing fluid (for example, strong acid, strong alkali, organic matter, and the like) used in the cleaning process. In particular, the PFA resin, which is often used as a material applied to the substrate processing apparatus, has a surface resistance higher than the surface resistance of the substrate W (about 10⁶ Ω). Thus, the PFA resin has high electronegativity, and thus it is easy to accumulate static electricity on the surface of the material due to friction with the processing fluid during the cleaning process. At this time, since the PFA resin is an insulator, the PFA resin does not have the ability to remove static electricity accumulated on the surface. In addition, the surface resistance of de-ionized water (DIW) also has a value similar to the surface resistance of the substrate W. Thus, if the DIW in contact with the substrate W is rubbed against the PFA resin during the cleaning process (for example, rinse process), static electricity may be generated and the substrate may be damaged due to the static electricity. Terms such as “about” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In order to solve such a problem, a reinforcing material may be added to the PFA resin to obtain a material (referred to as an antistatic material below) having an antistatic effect of removing static electricity, and the obtained material may be applied to the substrate processing apparatus.

Generally, a fluorine resin has physical properties that intends not to be mixed with other substances. Thus, it is not easy to cause an interaction between a fluororesin molecule and a reinforcing material molecule when the reinforcing material is mixed with the fluorine resin. For example, when a PFA resin and the reinforcing material are mixed, the PFA resin considers the reinforcing material as a foreign matter. Therefore, as the content of the reinforcing material added in the fluorine resin increases, the possibility of the reinforcing material acting as a particle source increases. In one example, the reinforcing material may be a carbon fiber (CF), which is a lightweight and high-strength material. A material obtained by mixing the carbon fiber with the PFA resin is referred to as a CF/PFA material below for the easy description.

Regarding CR6100, which is a CF/PFA material used as a material for a chuck pin and a chuck in the related art, a plate-shaped CR6100 is produced by pouring a liquid PFA resin into a textile-shaped carbon fiber (CF) to impregnate the PFA resin in an empty space in the textile-shaped carbon fiber (CF). Then, the part of the substrate processing apparatus is produced by using a method such as cutting processing. At this time, since the maximum thickness of the CR6100 plate that can be manufactured is 25 mm, there is a limit to the size of the parts that can be produced using the CR6100 plate. In addition, since the part is produced by cutting the CR6100 plate, there is a limit to the shape of the part that can be produced.

In order to solve the above-described problems, the substrate processing apparatus 300 according to the embodiment of the present invention may contain an antistatic material in which milled carbon fibers (MCF) are blended with a PFA resin. Specifically, the substrate support unit 340 according to the embodiment of the present invention may include or may be formed of an antistatic material in which milled carbon fibers (MCF) are blended with a PFA resin. For easy description, an antistatic material in which milled carbon fibers (MCF) are blended with a PFA resin is referred to as an MCF/PFA material below.

The milled carbon fiber (MCF) has a fiber length adjusted by finely cutting a carbon fiber (CF), and thus the fiber length (several pm) of the milled carbon fiber is shorter than the fiber length of a general carbon fiber (CF) having several tens of μm to hundreds of μm. That is, the carbon fiber (CF) and the milled carbon fiber (MCF) have the same composition but differ in the shape of the fiber.

The MCF/PFA material in the embodiment of the present invention may be applied to the substrate processing apparatus in a manner that a pellet is produced by blending milled carbon fibers (MCF) and a PFA resin, and then injection processing is performed on the pellet. As described above, since an injection processing method is used for the MCF/PFA material uses to produce parts, there is no limit to the size and shape of the parts that can be produced. In addition, because the injection processing method is used, the production time is shortened as compared to a part production method using the CR6100 material, which can also be advantageous for cost reduction.

Meanwhile, as the content of carbon fibers (CF) in the PFA resin increases, the electrical resistance of the mixed material is lowered, and thus it is possible to improve the antistatic effect. However, as described above, since the PFA resin considers the carbon fiber (CF) being the reinforcing material as the foreign matter, the possibility that the carbon fiber (CF) being the reinforcing material acts as the particle source may increase as the content of the carbon fiber (CF) increases. It is undesirable to use a material that is likely to be a particle source as a component of a process device in a cleaning process having a purpose that is to remove particles from the substrate W.

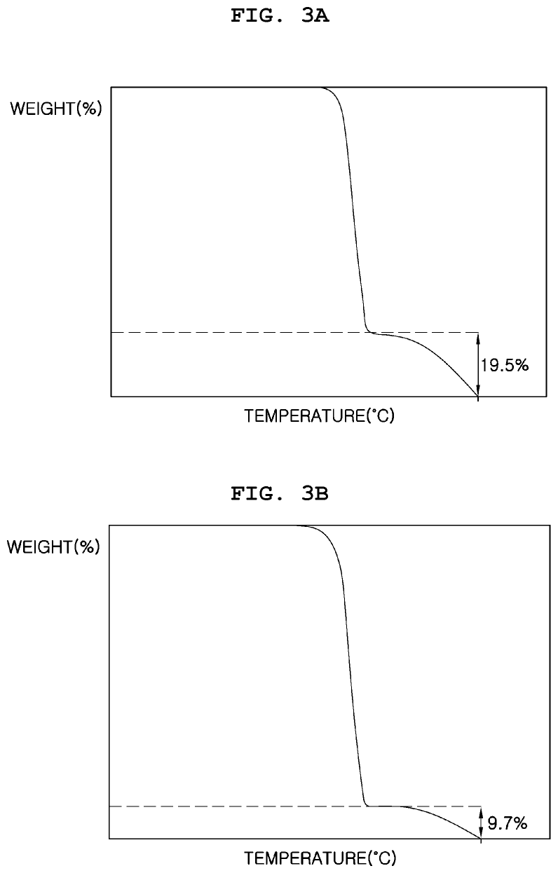

FIGS. 3A and 3B illustrate pyrolysis curves for comparing the CF/PFA material (CR6100) with an MCF/PFA material according to the embodiment of the present invention. FIG. 3A illustrates a pyrolysis curve of the CF/PFA material (CR6100). FIG. 3B illustrates a pyrolysis curve of the MCF/PFA material. The pyrolysis curve is a graph showing the weight change of a material according to a change in temperature, and the pyrolysis state of the material according to the temperature can be understood. Since pyrolysis appears to be a decrease in weight, the weight ratio of the material constituting the mixed material can be obtained by using the pyrolysis curve.

With reference to FIGS. 3A and 3B, it can be understood that the CF content in the CF/PFA material (CR6100) is 19.5%, and the CF content in the MCF/PFA material is 9.7%. As described above, when a milled carbon fiber (MCF) is used as the reinforcing material for the PFA resin, it is possible to obtain a material having resistance lower than the resistance of the substrate W with a lower reinforcing material content than that when a carbon fiber (CF) is used as the reinforcing material for the PFA resin. That is, by using the MCF/PFA material, it is possible to significantly reduce the probability that the reinforcing material acts as the particle source.

In addition, when the milled carbon fibers (MCF) are blended into the PFA resin as the reinforcing material, and then injection processing is performed, it can be understood that the surface of an injection article is clean, and a smearing phenomenon in a friction hardness test is improved, and the wear is reduced, as compared with the injection processing of only the PFA resin.

Table 1 shows comparison in physical properties between the known PFA resin and the MCF/PFA material according to the present invention.

TABLE 1

| | Chemical property | | | |
|---|---|---|---|---|
| | Acid | Alkali | Chemical | Electrical property |
| Properties | resistance | resistance | resistance | Surface resistance |
| PFA (ref.) | 0% | 0% | 0% | 10¹⁷⁻¹⁴ Ω |
| MCF/PFA | 0% | 0% | 0% | 10⁵⁻⁴ Ω |

| | | | | | Thermal | |
|---|---|---|---|---|---|---|
| | Mechanical property | | | Physical | property | |
| | | | Pencil | property | Coefficient | |
| | Flexural | Flexural | hardness | Specific | of linear | Injection |
| Properties | strength | modulus | wear rate | gravity | expansion | possibility |
| PFA (ref.) | 171 | 5600~7138 | 22% | 2.1~2.7 | 1.2~2.0 × | possible |
| | kg/cm² | kg/cm² | | g · cm¹ | 10⁻⁴/⁻C | |
| MCF/PFA | 279 | 31917 | 16% | 2.07 | 0.4 × | possible |
| | kg/cm² | kg/cm² | | g/cm¹ | 10⁻⁴/⁻C | |

With reference to Table 1, it can be understood that, by using the MCF/PFA material, while the chemical resistance and the injection possibility of the PFA resin are maintained, the flexural strength and the pencil hardness wear rate are significantly increased, the specific gravity is slightly lowered, and the coefficient of linear expansion is increased.

As shown in Table 1, the MCF/PFA material has relatively high mechanical properties as compared to the PFA resin. Thus, when the MCF/PFA material is applied to the chuck 342, it is expected that the chuck 342 has a higher service time than a mass production PFA chuck in the related art.

Thus, the chuck 342 according to the embodiment of the present invention may be formed by a method of blending milled carbon fibers (MCF) into a perfluoroalkoxy alkane (PFA) resin and then performing injection processing.

The chuck 342 may be formed in a form of containing an antistatic material in which milled carbon fibers (MCF) are blended with a perfluoroalkoxy alkane (PFA) resin in the chuck 342.

A plurality of support pins 344 are provided. The support pins 344 are arranged at predetermined intervals on the edge of the upper surface of the chuck 342 and protrude upward from the chuck 342. The support pins 344 are arranged to have an overall annular ring shape by combination with each other. The support pin 344 supports the rear edge of the substrate W such that the substrate W is spaced at a predetermined distance from the upper surface of the chuck 342.

A plurality of chuck pins 346 are provided. The chuck pins 346 are disposed more distant from the center of the chuck 342 than the support pin 344. The chuck pins 346 are provided to protrude upward from the upper surface of the chuck 342. The chuck pins 346 support or contact the side portion of the substrate W so that the substrate

W is not laterally deviated from the correct position when the chuck 342 is rotated. The chuck pins 346 are provided to enable linear movement between an outer position and an inner position along the radial direction of the chuck 342. The outer position is farther away from the center of the chuck 342 than the inner position. When the substrate W is loaded or unloaded on the chuck 342, the chuck pins 346 are located at the outer position. When the process is performed on the substrate W, the chuck pins 346 are located at the inner position. The inner position is a position at which the side portions of the chuck pin 346 and the substrate W are in contact with each other. The outer position is a position at which the chuck pins 346 and the substrate W are at a distance from each other. The chuck pins 346 may include or may be famed of a conductive material. In some embodiments, the chuck pins 346 may include or may be formed of a material having resistance lower than the substrate W. In addition, the chuck pins 346 may include or may be formed of a material having resistance lower than the MCF/PFA material forming the chuck 342.

The rotational drive member 350 rotates the chuck 342. The chuck 342 is rotatable about a magnetic center axis by the rotational drive member 350. The rotational drive member 350 includes a support shaft 352 and a rotational drive unit 354. The support shaft 352 has a barrel shape directed in the third direction 16. The upper end of the support shaft 352 is fixedly coupled to the bottom surface of the chuck 342. According to one example, the support shaft 352 may be fixedly coupled to the bottom center of the chuck 342. The rotational drive unit 354 provides a driving force to rotate the support shaft 352. The support shaft 352 is rotated by the rotational drive unit 354, and the chuck 342 is rotatable with the support shaft 352.

The lifting unit 360 linearly moves the recovery unit 320 up and down. The relative height of the recovery unit 320 to the chuck 342 is changed as the recovery unit 320 is moved up and down. When the substrate W is loaded or unloaded on the chuck 342, the lifting unit 360 lowers the recovery unit 320 so that the chuck 342 protrudes from the top of the recovery unit 320. In addition, when the process is in progress, the height of the recovery unit 320 is adjusted so that the processing fluid flows into the predetermined recovery cup 322 or 326 in accordance with the type of the processing fluid supplied to the substrate W. The lifting unit 360 includes a bracket 362, a moving shaft 364, and a driver 366. The bracket 362 is fixedly installed on the outer wall of the recovery unit 320, and the moving shaft 364 moved up and down by the driver 366 is fixedly coupled to the bracket 362. Optionally, the lifting unit 360 may move the chuck 342 up and down.

The upper fluid supply unit 380 supplies the processing fluid onto the upper surface of the substrate W. The upper surface of the substrate may be a patterned surface. A plurality of upper fluid supply units 380 may be provided, each of the upper fluid supply units 380 may supply a different kind of processing fluid. The upper fluid supply unit 380 includes a moving member 381 and a nozzle 390.

The moving member 381 moves the nozzle 390 to a process position and a standby position. Here, the process position is a position at which the nozzle 390 faces the substrate W supported by the substrate support unit 340. The standby position is defined as a position at which the nozzle 390 is out of the process position. According to one example, the process position includes a preprocessing position and a post-processing position. The preprocessing position is a position at which the nozzle 390 supplies the processing fluid to a first supply position. The post-processing position is provided as a position at which the nozzle 390 supplies the processing fluid to a second supply position. The first supply position may be closer to the center of the substrate W than the second supply position, and the second supply position may be a position including the end portion of the substrate. Optionally, the second supply position may be an area near the end portion of the substrate.

The moving member 381 includes a support shaft 386, an arm 382, and a driver 388. The support shaft 386 is located on one side of the recovery unit 320. The support shaft 386 has a rod shape having the longitudinal direction that is directed in the third direction. The support shaft 386 is provided to be rotatable by the driver 388. The support shaft 386 is provided to be lifted. The arm 382 is coupled to the top of the support shaft 386. The arm 382 extends vertically from the support shaft 386. The nozzle 390 is fixedly coupled to the end of the arm 382. As the support shaft 386 is rotated, the nozzle 390 can swing with the arm 382. The nozzle 390 can be moved to the process position and the standby position by swinging. Optionally, the arm 382 may be provided to enable forward and backward movement in the longitudinal direction of the arm 382. A path through which the nozzle 390 is moved when viewed from the top may coincide with the center axis of the substrate W at the process position. For example, the processing fluid may be a chemical, a rinse liquid, and an organic solvent. The chemical may be a liquid having acid or base properties. The chemical may include sulfuric acid (H₂SO₄), phosphoric acid (P₂O₅), hydrofluoric acid (HF), and ammonium hydroxide (NH₄OH). The rinse liquid may be pure water (H₂O). The organic solvent may be isopropyl alcohol (IPA) liquid.

The bottom fluid supply unit 400 washes and dries the bottom surface of the substrate W. The bottom fluid supply unit 400 supplies a processing fluid onto the bottom surface of the substrate W. The bottom surface of the substrate W may be a non-patterned surface opposite to the surface on which the pattern is formed. The bottom fluid supply unit 400 may supply the processing fluid simultaneously with the upper fluid supply unit 380. The bottom fluid supply unit 400 may be fixed not to rotate. The substrate processing apparatus 300 according to the embodiment of the present invention includes the bottom fluid supply unit 400, as an example. The bottom fluid supply unit 400 may be omitted depending on the processing process using the substrate processing apparatus 300.

Although not described in detail in the present invention, the substrate processing apparatus 300 may further include an airflow supply unit. The airflow supply unit supplies an external gas to the processing space 321. The airflow supply unit may form a descending airflow in the processing space. The airflow supply unit may include a cover (not illustrated), a gas supply line (not illustrated), a fan (not illustrated), and a filter (not illustrated). The airflow supply unit may be controlled by a controller (not illustrated) which will be described later.

The controller (not illustrated) may control the substrate processing facility 1. The controller (not illustrated) may control the substrate processing apparatus 300. The controller (not illustrated) may control the rotational drive member 350. The controller (not illustrated) may control the rotational drive unit 354. In addition, the controller (not illustrated) may control the upper fluid supply unit 380 and the bottom fluid supply unit 400. For example, the controller (not illustrated) is a computer, and may include a control unit and a storage unit. The storage unit may store a program for controlling various processes performed in the substrate processing facility 1. The control unit may control the operation of the substrate processing facility 1 by reading and executing the program stored in the storage unit.

The chuck pins 346 may be electrically connected to the chuck 342, and the chuck 342 may be grounded. Specifically, the chuck 342 may be electrically connected to the rotational drive member 350, and the rotational drive member 350 may be grounded. More specifically, the rotational drive unit 354 may be grounded. That is, the chuck 342 that is electrically connected to the rotational drive member 350 including the rotation drive unit 354 can be grounded by grounding the rotational drive unit 354.

The substrate processing apparatus 300 according to the embodiment of the present invention can remove static electricity on the substrate W by causing the static electricity generated on the substrate W to flow via the substrate support unit 340 and the rotational drive member 350 to have a ground potential. Specifically, the static electricity generated on the substrate W can be removed by moving along the chuck pins 346, the chuck 342, the support shaft 352, and the rotational drive unit 354. At this time, the chuck pins 346 may include or may be formed of a conductive material and a material having resistance lower than each of the substrate W and the chuck 342. In some embodiments, the chuck pins 346 may include or may be formed of a resin.

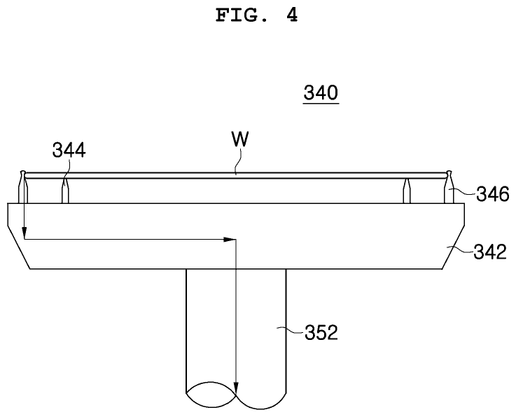

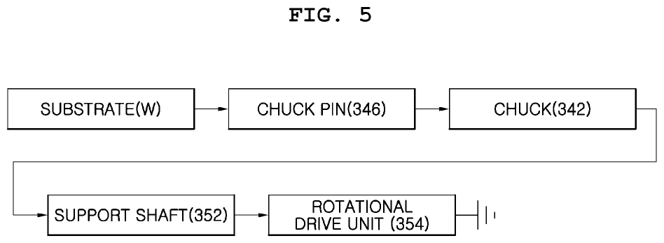

FIGS. 4 and 5 illustrate a procedure in which static electricity generated on the substrate is removed by the substrate processing apparatus according to the embodiment of the present invention.

As indicated by the arrow in FIG. 4, static electricity generated on the substrate W may be moved to the chuck pins 346 having resistance lower than the substrate W, and be transmitted to the inside of the chuck 342.

Since the chuck 342 according to the embodiment of the present invention incudes or is formed of an MCF/PFA material in which milled carbon fibers (MCF) are blended into a perfluoroalkoxy alkane (PFA) resin, and the chuck 342 is in contact with the chuck pins 346, static electricity generated on the substrate W is moved to the chuck pins 346 and is transmitted to the inside of the chuck 342.

As illustrated in FIG. 5, static electricity guided to the chuck 342 may be transmitted to the support shaft 352. The support shaft 352 may include or may be formed of a conductive material. As an example, the support shaft 352 may include or may be formed of an MCF/PFA material. The static electricity that is continuously guided to the support shaft 352 can be transmitted to the grounded rotational drive unit 354 and then removed. The rotational drive unit 354 may include or may be famed of a conductive material. As an example, the rotational drive unit 354 may include or may be formed of an MCF/PFA material.

### MODIFICATION EXAMPLES

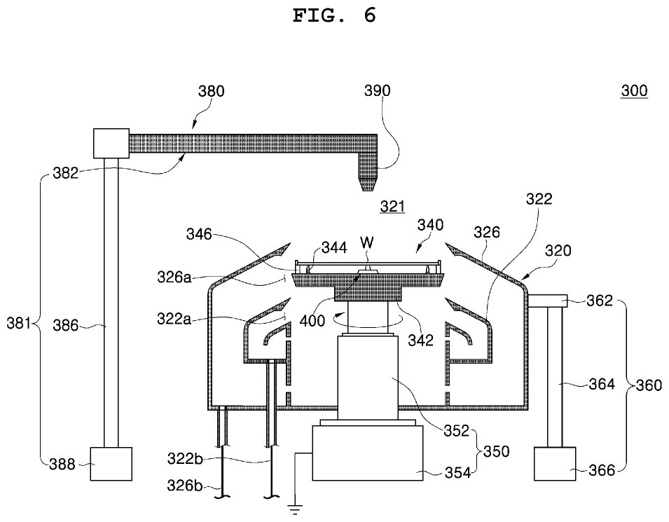

FIG. 6 is a diagram illustrating a configuration of a substrate processing apparatus according to a modification example of the present invention.

In the above-described embodiment, static electricity generated on the substrate W is discharged to the ground potential via the chuck pins 346, the chuck 342, the support shaft 352, and the rotational drive unit 354.

At this time, in order to obtain a more effective antistatic effect, at least one of the components disposed around the substrate W, such as the recovery unit 320 and the upper fluid supply unit 380, may include or may be formed of an MCF/PFA material.

As an example, as illustrated in FIG. 6, an MCF/PFA material may be applied to all the chuck 342, the recovery unit 320, and the upper fluid supply unit 380. As an example, the chuck 342, the recovery cups 322 and 326, and the nozzle 390 may all be produced by injection processing by blending milled carbon fibers (MCF) into a perfluoroalkoxy alkane (PFA) resin, and then may be disposed in the substrate processing apparatus 300. Thus, static electricity generated on the substrate W is grounded by the chuck pins 346 and is removed by being charged to the recovery unit 320 and the upper fluid supply unit 380 around the substrate W. Accordingly, it is possible to further maximize the effect of removing the static electricity. At this time, the recovery unit 320 and the upper fluid supply unit 380 may be grounded. Specifically, the recovery cups 322 and 326, and the nozzle 390 may be grounded.

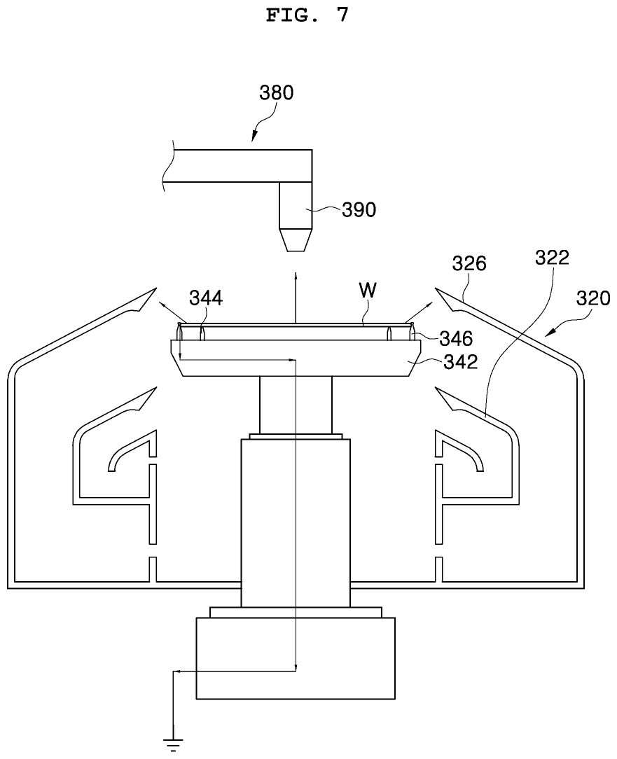

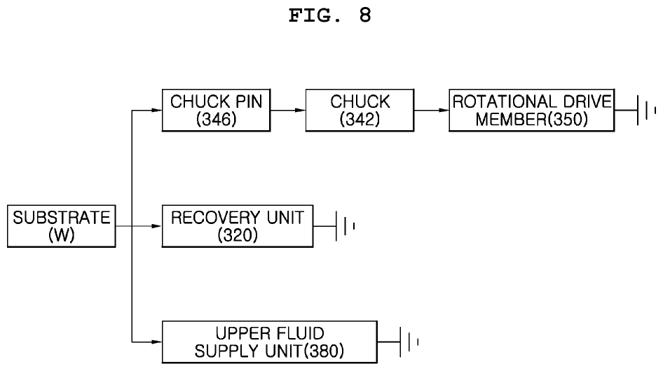

FIGS. 7 and 8 illustrate a procedure in which static electricity generated on the substrate is removed by the substrate processing apparatus according to the first modification example.

As indicated by the arrow in FIG. 7, static electricity generated on the substrate W can be removed by being charged to the recovery unit 320 and the upper fluid supply unit 380 and be removed in the same manner as the above-described embodiment.

As illustrated in FIG. 8, by configuring various conduction paths of static electricity generated on the substrate W, it is possible to maximize the effect of removing static electricity. In addition, it is possible to prevent conduction to an unintended path.

In the first modification example of the present invention, the MCF/PFA material is applied to all the chuck 342, the recovery cups 322 and 326, and the nozzle 390 located close to the substrate W, but the MCF/PFA material may be applied only to the chuck 342 and the nozzle 390 except for the recovery cups 322 and 326. Alternatively, the MCF/PFA material may be applied only to the chuck 342 and the recovery cups 322 and 326 except for the nozzle 390. At this time, the recovery cups 322 and 326 to which the MCF/PFA material is applied or the nozzle 390 to which the MCF/PFA material is applied can be grounded. That is, the component parts to which the MCF/PFA material is applied among the recovery cups 322 and 326 and the nozzle (390) can be grounded.

In order to maximize the antistatic effect of the substrate processing apparatus, it is preferable that the MCF/PFA material be applied to all the chuck 342, the recovery cups 322 and 326, and the nozzle 390. Further, the component parts to which the MCF/PFA material is applied are preferably grounded.

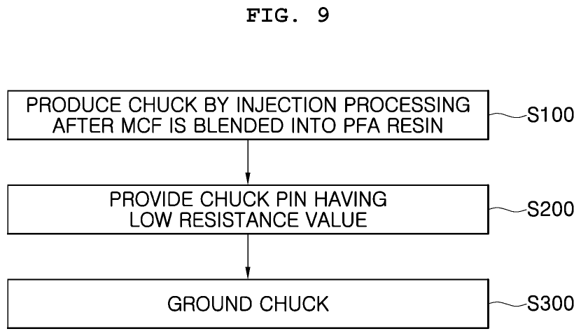

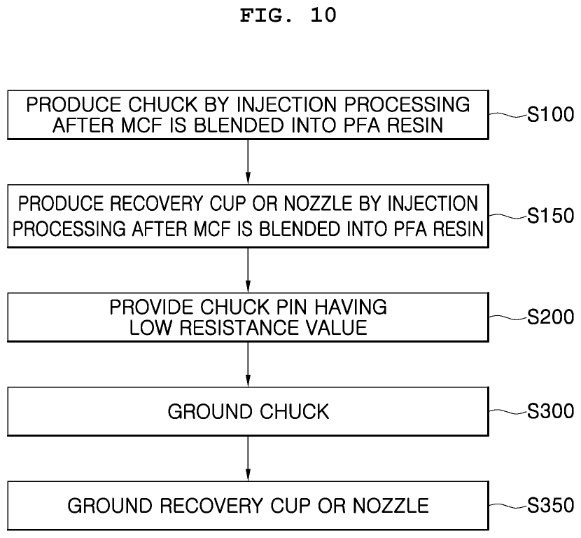

Meanwhile, according to the embodiment of the present invention, a manufacturing method of the above-described substrate processing apparatus may be provided. FIG. 9 is a flow chart illustrating the manufacturing method of the substrate processing apparatus according to the embodiment of the present invention. FIG. 10 is a flow chart illustrating a manufacturing method of the substrate processing apparatus according to a modification example of FIG. 9.

With reference to FIG. 9, the manufacturing method of the substrate processing apparatus according to the embodiment of the present invention includes a step S100 of producing a chuck 342 by injection processing by blending milled carbon fibers (MCF) into a perfluoroalkoxy alkane (PFA) resin, a step S200 of providing chuck pins 346 with a conductive material having a resistance value lower than a substrate W, and a step S300 of grounding the chuck 342. At this time, the milled carbon fiber (MCF) is obtained by performing finely cutting fiber length processing of finely cutting a carbon fiber. When the milled carbon fiber is contained as the reinforcing material in the PFA, it is possible to realize the same resistance with a lower content of the reinforcing material than when the carbon fiber is contained as the reinforcing material of the PFA. Since the chuck pins 346 is provided with a conductive material having a resistance value lower than the substrate W, static electricity generated on the substrate can move to the chuck pins 346. In addition, the chuck 342 is grounded, and thus the static electricity moved to the chuck pins 346 that electrically connects the substrate W and the chuck 342 can be removed via the chuck 342.

As a modification example of the embodiment described above, as illustrated in FIG. 10, a step S150 of producing at least one of the recovery cups 322 and 326 and the nozzle 390 by injection processing by blending milled carbon fibers (MCF) into a perfluoroalkoxy alkane (PFA) resin, and a step S350 of grounding the recovery cups 322 and 326 or the nozzle 390 may be further provided. According to the manufacturing method of a substrate processing apparatus according to the modification example of the present invention, guided charging is caused on the substrate by the recovery cups 322 and 326 or the nozzle 390 that is grounded and produced by injection processing by blending milled carbon fibers (MCF) into a perfluoroalkoxy alkane (PFA) resin, and thus erasing through the chuck 342 and erasing by guided charging occur at the same time. Thus, it is possible to improve the antistatic effect on the substrate.

As an example, the step S150 of producing the recovery cups 322 and 326 and the nozzle 390 by injection processing by blending milled carbon fibers (MCF) into a perfluoroalkoxy alkane (PFA) resin may be performed next to the step S100 of producing the chuck 342 by injection processing by blending milled carbon fibers (MCF) into a perfluoroalkoxy alkane (PFA) resin. At this time, after the step S300 of grounding the chuck 342, the step S350 of grounding the recovery cups 322 and 326 and the nozzle 390 may be further performed.

Alternatively, only one of the recovery cups 322 and 326 and the nozzle 390 may be produced with the MCF/PFA material in the step S150, and only parts produced with the MCF/PFA material among the recovery cups 322 and 326 and the nozzle 390 may be grounded in the step S350.

As described above, in the substrate processing apparatus, the substrate processing facility including the substrate processing apparatus, and the manufacturing method of the substrate processing apparatus according to the embodiment and the modification examples of the present invention, since the antistatic material capable of more effectively removing static electricity as compared to the antistatic material in the related art is applied to the substrate processing apparatus, it is possible to efficiently remove static electricity generated on the substrate. Thus, it is possible to minimize particle contamination of a substrate, an occurrence of an arcing phenomena on the surface of the substrate, and damage to the pattern of the substrate, which are caused by static electricity generated on the substrate.

As described above, the liquid processing process has been described using the cleaning process as an example, but the liquid processing process according to the embodiment of the present invention can be applied to a process of processing a substrate by using the processing fluid, such as a coating process, a development process, an etching process, and an asking process.

Those skilled in the art should understand that the present invention may be embodied in other specific forms without changing the technical spirit or essential characteristics thereof, so the embodiments described above are illustrative in all aspects and are not restrictive.

It will be apparent that the present embodiment and the drawings attached to this specification just clearly represent a part of the technical spirit included in the present invention, and all modification examples and specific embodiments that can be easily inferred by those skilled in the art within the scope of the technical spirit contained in the specification and drawings of the present invention are included in the scope of the present invention.

Therefore, the spirit of the present invention should not be limited to the described embodiments, and not only the claims to be described later, but also all those that have equal or equivalent modifications to the claims will be said to belong to the scope of the spirit of the present invention.

What is claimed is:

1. A substrate processing apparatus comprising:
a substrate support unit that includes a chuck for supporting a substrate;
a fluid supply unit that supplies a processing fluid to the substrate; and
a recovery unit surrounding the chuck and configured to recover the supplied processing fluid,
wherein the substrate support unit contains an antistatic material in which milled carbon fibers (MCF) are blended into a perfluoroalkoxy alkane (PFA) resin.

2. The substrate processing apparatus according to claim 1,
wherein the chuck of the substrate support unit is configured to be rotatable,
wherein the substrate support unit further includes:
a support pin fixed to an upper surface of the chuck, and
a chuck pin protruding from the upper surface of the chuck,
wherein the chuck pin is more distant from a center of the upper surface of the chuck than the support pin so that the chuck pin and the support pin contact an edge of the substrate and a rear surface of the substrate, respectively, and
wherein the chuck is formed of MCF and a PFA resin, the MCF being blended into the PFA resin.

3. The substrate processing apparatus according to claim 2,
wherein the chuck pin is formed of a conductive material having resistance lower than the substrate.

4. The substrate processing apparatus according to claim 3,
wherein the chuck pin is electrically connected to the chuck, and the chuck is electrically grounded.

5. The substrate processing apparatus according to claim 1,
wherein the MCF is a finely-cut carbon fiber.

6. The substrate processing apparatus according to claim 5,
wherein at least one of the fluid supply unit and the recovery unit contains the antistatic material.

7. The substrate processing apparatus according to claim 6,
wherein the fluid supply unit includes a nozzle for discharging the processing fluid onto an upper surface of the substrate,
wherein the recovery unit includes a recovery cup for recovering the used processing fluid, and
wherein at least one of the nozzle and the recovery cup includes MCF and a PFA resin, the MCF being blended into the PFA resin.

8. The substrate processing apparatus according to claim 7,
wherein at least one of the fluid supply unit and the recovery unit is electrically grounded.

9. A substrate processing facility comprising:
a load port on which a carrier storing a substrate is mounted;
a transport frame in which an index robot that conveys the substrate from the carrier mounted on the load port is provided; and
a process processing module including a substrate processing apparatus that performs a liquid processing process on the substrate,
wherein the substrate processing apparatus includes:
a substrate support unit that includes a chuck for supporting the substrate,
a fluid supply unit that supplies a processing fluid to the substrate, and
a recovery unit surrounding the chuck and configured to recover the supplied processing fluid, and
wherein the substrate support unit includes an antistatic material in which milled carbon fibers (MCF) are blended into a perfluoroalkoxy alkane (PFA) resin.

10. The substrate processing facility according to claim 9,
wherein the chuck of the substrate support unit is configured to be rotatable,
wherein the substrate support unit further includes:
a support pin fixed to an upper surface of the chuck, and
a chuck pin protruding from the upper surface of the chuck, and
wherein the chuck pin is more distant from a center of the upper surface of the chuck than the support pin so that the chuck pin and the support pin contact an edge of the substrate and a rear surface of the substrate, respectively, and
wherein the chuck is formed of the MCF and the PFA resin, the MCF being blended into the PFA resin.

11. The substrate processing facility according to claim 10,
wherein the chuck pin is formed of a conductive material having resistance lower than the chuck.

12. The substrate processing facility according to claim 11,
Wherein the chuck pin is electrically connected to the chuck, and the chuck is electrically grounded.

13. The substrate processing facility according to claim 9,
wherein the MCF is a finely-cut carbon fiber.

14. The substrate processing facility according to claim 13,
wherein at least one of the fluid supply unit and the recovery unit contains the antistatic material.

15. The substrate processing facility according to claim 14,
wherein the fluid supply unit includes a nozzle for discharging the processing fluid onto an upper surface of the substrate,
wherein the recovery unit includes a recovery cup for recovering the used processing fluid, and
wherein at least one of the nozzle and the recovery cup includes MCF and a PFA resin, the MCF being blended into the PFA resin.

16. The substrate processing facility according to claim 15,
wherein at least one of the fluid supply unit and the recovery unit is electrically grounded.

17. A manufacturing method of a substrate processing apparatus including a substrate support unit that includes a chuck for supporting a lower surface of a substrate and a chuck pin formed to come into contact with a side surface portion of the substrate, a fluid supply unit that supplies a processing fluid to the substrate, and a recovery unit that is disposed to surround the chuck and recovers the supplied processing fluid, the method comprising:
producing the chuck by injection processing by blending milled carbon fibers (MCF) into a perfluoroalkoxy alkane (PFA) resin;
providing the chuck pin with a conductive material having resistance lower than the substrate; and
grounding the chuck.

18. The manufacturing method of a substrate processing apparatus according to claim 17,
wherein the MCF is a finely-cut carbon fiber.

19. The manufacturing method of a substrate processing apparatus according to claim 18, further comprising:
producing at least one of a nozzle provided in the fluid supply unit and a recovery cup provided in the recovery unit,
wherein at least one of the nozzle and the recovery cup includes blending MCF and a PFA resin, the MCF being blended into the PFA resin.

20. The manufacturing method of a substrate processing apparatus according to claim 19, further comprising:
electrically grounding the fluid supply unit or the recovery unit.
